(19) United States
(12) Patent Application Publication
(10) Pub. No.: US 2026/0155817 A1
(43) Pub. Date: Jun. 4, 2026

(54) SWITCHING CONTROL CIRCUIT AND POWER SOURCE SYSTEM

(71) Applicant: FUJI ELECTRIC CO., LTD., Kanagawa (JP)

(72) Inventor: Hiroki YAMANE, Matsumoto-city (JP)

(21) Appl. No.: 19/339,159

(22) Filed: Sep. 24, 2025

(30) Foreign Application Priority Data
Nov. 29, 2024 (JP) 2024-208849

(51) Int. Cl. H03K 17/082; H03K 7/06; H03K 17/13; H03K 17/08

(52) U.S. Cl. CPC H03K 17/0822; H03K 7/06; H03K 17/133; H03K 2017/0806; H03K 2217/0027

(57) ABSTRACT

A switching control circuit which controls a switching device included in a power source system which generates an output voltage from an AC input voltage, includes an input detection voltage acquisition unit which acquires an input detection voltage corresponding to the AC input voltage, a current detection voltage acquisition unit which acquires a current detection voltage generated in a current detection resistor which detects a current flowing through the switching device, a short circuit determination unit which determines, by comparing the current detection voltage with a predetermined short circuit threshold voltage, whether or not the current detection resistor is short circuited, and a driving unit which drives the switching device by a pulse width modulation method or a pulse frequency modulation method.

The contents of the following patent application(s) are incorporated herein by reference: NO. 2024-208849 filed in JP on November 29, 2024.

### BACKGROUND

### 1. TECHNICAL FIELD

The present invention relates to a switching control circuit and a power source system.

### 2. RELATED ART

Patent Document 1 describes a "switch control apparatus provided with a protection function concerning short circuit or the like of a sense resistor".

### RELATED ART DOCUMENTS

### PATENT DOCUMENTS

Patent Document 1: Japanese Patent Application Publication No. 2020-061821

Patent Document 2: Japanese Patent Application Publication No. 2020-089033

Patent Document 3: Japanese Patent Application Publication No. 2015-177594

Patent Document 4: Japanese Patent Application Publication No. 2024-017055

### BRIEF DESCRIPTION OF THE DRAWINGS

FIG. 1 illustrates an overview of a configuration of a switching control circuit 100.

FIG. 2 illustrates an overview of a configuration of a modified example of the switching control circuit 100.

FIG. 3A illustrates an example of a power source system 10 which includes the switching control circuit 100.

FIG. 3B illustrates an example of the switching control circuit 100.

FIG. 4 illustrates an example of an input detection voltage and a determination value.

FIG. 5 illustrates an example of the power source system 10 which includes the switching control circuit 100.

FIG. 6 illustrates an example of the power source system 10 which includes the switching control circuit 100.

FIG. 7 illustrates an example of an auxiliary winding voltage Vzcd.

FIG. 8 illustrates an example of the input detection voltage and the determination value.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solving means of the invention.

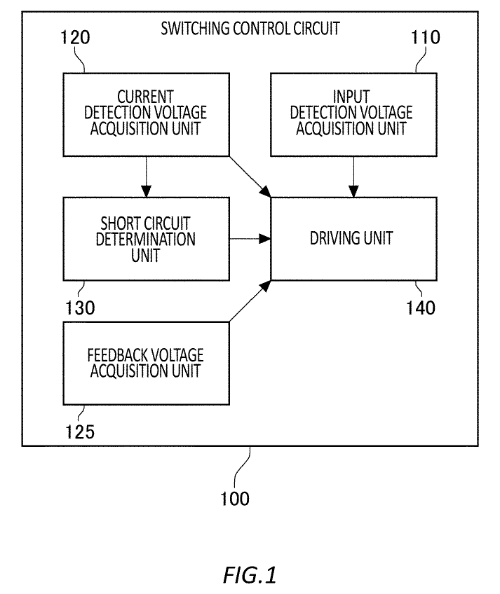

FIG. 1 illustrates an overview of a configuration of a switching control circuit 100. The switching control circuit 100 of the present example is a switching control circuit which controls a switching device included in a power source system which generates an output voltage from an AC input voltage. The switching control circuit 100 includes an input detection voltage acquisition unit 110, a current detection voltage acquisition unit 120, a feedback voltage acquisition unit 125, a short circuit determination unit 130, and a driving unit 140.

The input detection voltage acquisition unit 110 acquires an input detection voltage corresponding to an AC input voltage. The input detection voltage acquisition unit 110 may acquire, as the input detection voltage, a voltage obtained by performing full-wave rectification on the AC input voltage. The input detection voltage acquisition unit 110 may acquire, as the input detection voltage, a voltage obtained when a voltage drop due to a resistor occurs in the voltage obtained by performing full-wave rectification on the AC input voltage. The input detection voltage acquisition unit 110 may acquire, as the input detection voltage, a voltage which is obtained when the AC input voltage is subjected to full-wave rectification and divided. The input detection voltage acquisition unit 110 may acquire, as the input detection voltage, a voltage generated in an auxiliary winding when the voltage obtained by performing full-wave rectification on the AC input voltage is input to a main winding of a transformer. The input detection voltage acquisition unit 110 may acquire, as the input detection voltage, a voltage obtained by dividing the voltage generated in the auxiliary winding when the voltage obtained by performing full-wave rectification on the AC input voltage is input to the main winding of the transformer. It is noted however that the input detection voltage acquired by the input detection voltage acquisition unit 110 is not limited to these examples. The input detection voltage acquisition unit 110 may supply the input detection voltage to the driving unit 140.

The current detection voltage acquisition unit 120 acquires a current detection voltage generated in a current detection resistor which detects a current flowing through the switching device. The switching device may be a device configured to generate an output voltage from the AC input voltage in the power source system. The current detection resistor may be a resistor which is connected in series to the switching device and is configured to detect a current flowing through the switching device. Details of the switching device and the current detection resistor will be described below. The current detection voltage acquisition unit 120 may supply the current detection voltage to the short circuit determination unit 130 and the driving unit 140.

The feedback voltage acquisition unit 125 acquires a feedback voltage corresponding to an output voltage. The feedback voltage acquisition unit 125 may acquire a feedback voltage generated depending on an output voltage. For example, the feedback voltage is generated by using a photocoupler depending on the output voltage. The feedback voltage acquisition unit 125 may acquire a feedback voltage obtained by dividing the output voltage at a predetermined division ratio.

The short circuit determination unit 130 determines, by comparing the current detection voltage with a predetermined short circuit threshold voltage, whether or not the current detection resistor is short circuited. The short circuit determination unit 130 may determine that the current detection resistor is short circuited when the current detection voltage does not exceed the short circuit threshold voltage within a predetermined period of time after the switching device is turned on. The short circuit determination unit 130 may supply, to the driving unit 140, a determination result obtained by determining whether or not the current detection resistor is short circuited.

The driving unit 140 drives the switching device. The driving unit 140 may drive the switching device based on at least one of the input detection voltage, the current detection voltage, the feedback voltage, or the determination result. The driving unit 140 may drive the switching device by a pulse width modulation method. The driving unit 140 may drive the switching device by a pulse frequency modulation method.

For example, when the driving unit 140 drives the switching device by the pulse width modulation method, the driving unit 140 drives the switching device by setting a duty ratio for controlling the switching device. The driving unit 140 may set the duty ratio such that an output voltage of the power source system becomes constant. The driving unit 140 may set the duty ratio such that the output voltage of the power source system becomes constant based on the current detection voltage and a feedback signal corresponding to the output voltage.

When the short circuit determination unit 130 determines that the current detection resistor is short circuited, the driving unit 140 changes the duty ratio for controlling the switching device to a predetermined first duty ratio. The first duty ratio may be smaller than a maximum duty ratio that is preset in the switching control circuit 100. For example, the first duty ratio is 50% of the maximum duty ratio. The first duty ratio may be a duty ratio that does not cause a destructive failure due to self-heating of the switching device.

When the current detection resistor is short circuited, since the current detection voltage does not increase, it is not possible to perform comparison with the feedback signal corresponding to the output voltage, and a pulse width for controlling the switching device becomes maximum. In this case, there is a risk that the current which flows through the switching device may become excessive, and the switching device may suffer the destructive failure due to self-heating. Alternatively, the output voltage increases, and the switching device is stopped through an output overvoltage protection operation. To avoid the destructive failure of the switching device, the switching device with a rated current value larger than a capacity of the power source system may need to be used.

The switching control circuit 100 of the present example includes the short circuit determination unit 130 and the driving unit 140, and when it is determined that the current detection resistor is short circuited, the driving unit 140 changes the duty ratio to the first duty ratio. With this configuration, since a stress due to heat generation of the switching device can be reduced, even when the switching device with a small rated current value is used, the destructive failure of the switching device can be avoided.

In addition, in the switching control circuit 100 of the present example, when it is determined that the current detection resistor is short circuited, the driving unit 140 changes the duty ratio to the first duty ratio without stopping the switching device. With this configuration, even when short circuit of the current detection resistor is erroneously detected due to an instantaneous voltage drop or the like of the AC input voltage, the switching control circuit 100 of the present example can avoid the destructive failure of the switching device while the output voltage is being generated. Therefore, the switching control circuit 100 of the present example can improve efficiency as compared to a case where the switching device is stopped in response to short circuit detection.

A flow of a determination by the short circuit determination unit 130 on whether or not short circuit of the current detection resistor occurs and of a change of the duty ratio by the driving unit 140 may be performed for each switching cycle of the switching device. For example, in a case where it is determined that short circuit occurs in a certain cycle and the duty ratio is changed to the first duty ratio, when it is determined that short circuit does not occur in the next cycle, the driving unit 140 may end control by the first duty ratio and return to normal control. As another example, in a case where it is determined that short circuit occurs in a certain cycle and the duty ratio is changed to the first duty ratio, when it is still determined that short circuit also occurs in the next cycle, the driving unit 140 may continue the control by the first duty ratio.

When a number of at least one switching event of the switching device at the first duty ratio exceeds a predetermined reference number, the driving unit 140 may change the duty ratio for controlling the switching device to a second duty ratio that is smaller than the first duty ratio. For example, the second duty ratio is a predetermined minimum duty ratio for driving the switching device or 0. The predetermined reference number may be eight or may be 16. It is noted however that the reference number is not limited to these.

In the switching control circuit 100 of the present example, when the number of switching events of the switching device at the first duty ratio exceeds the predetermined reference number, the driving unit 140 changes the duty ratio to the second duty ratio that is smaller than the first duty ratio. When the number of switching events at the first duty ratio exceeds the reference number, there is a high probability that the current detection resistor is actually short circuited. Therefore, since the driving unit 140 changes the duty ratio to the second duty ratio that is smaller than the first duty ratio, the switching control circuit 100 of the present example can avoid the destructive failure of the switching device when short circuit actually occurs. On the other hand, when short circuit detection is an erroneous detection, that is, when normal control is reinstated before the number of switching events at the first duty ratio exceeds the reference number, the switching control circuit 100 of the present example can improve the efficiency as compared to a case where the switching device is stopped in response to short circuit detection.

As another example, when the driving unit 140 drives the switching device by the pulse frequency modulation method, the driving unit 140 drives the switching device by setting an ON width for turning on the switching device. The driving unit 140 may set the ON width such that the output voltage of the power source system becomes constant. The driving unit 140 may set the ON width such that the output voltage of the power source system becomes constant based on the current detection voltage and a feedback signal corresponding to the output voltage.

When the short circuit determination unit 130 determines that the current detection resistor is short circuited, the driving unit 140 changes the ON width for turning on the switching device to a predetermined first ON width. The first ON width may be shorter than a maximum ON width that is preset in the switching control circuit. For example, the first ON width is 50% of the maximum ON width. The first ON width may be an ON width that does not cause a destructive failure due to self-heating of the switching device.

The switching control circuit 100 of the present example includes the short circuit determination unit 130 and the driving unit 140, and the driving unit 140 changes the ON width to the first ON width when it is determined that the current detection resistor is short circuited. With this configuration, since a stress due to heat generation of the switching device can be reduced, even when the switching device with a small rated current value is used, the destructive failure of the switching device can be avoided.

In addition, in the switching control circuit 100 of the present example, when it is determined that the current detection resistor is short circuited, the driving unit 140 changes the ON width to the first ON width without stopping the switching device. With this configuration, even when short circuit of the current detection resistor is erroneously detected due to an instantaneous voltage drop or the like of the AC input voltage, the switching control circuit 100 of the present example can avoid the destructive failure of the switching device while the output voltage is being generated. Therefore, the switching control circuit 100 of the present example can improve the efficiency as compared to a case where the switching device is stopped in response to short circuit detection.

A flow of a determination by the short circuit determination unit 130 on whether or not short circuit of the current detection resistor occurs and of a change of the ON width by the driving unit 140 may be performed for each switching cycle of the switching device. For example, in a case where it is determined that short circuit occurs in a certain cycle and the ON width is changed to the first ON width, when it is determined that short circuit does not occur in the next cycle, the driving unit 140 may end the control by the first ON width and return to normal control. As another example, in a case where it is determined that short circuit occurs in a certain cycle and the ON width is changed to the first ON width, when it is still determined that short circuit also occurs in the next cycle, the driving unit 140 may continue the control by the first ON width.

When the number of switching events of the switching device at the first ON width exceeds a predetermined reference number, the driving unit 140 may change the ON width for turning on the switching device to a second ON width that is shorter than the first ON width. For example, the second ON width is a predetermined minimum ON width for driving the switching device or 0. The predetermined reference number may be eight or may be 16. It is noted however that the reference number is not limited to these.

In the switching control circuit 100 of the present example, when the number of switching events of the switching device at the first ON width exceeds the predetermined reference number, the driving unit 140 changes the ON width to the second ON width that is shorter than the first ON width. When the number of switching events at the first ON width exceeds the reference number, there is a high probability that the current detection resistor is actually short circuited. Therefore, since the driving unit 140 changes the ON width to the second ON width that is shorter than the first ON width, the switching control circuit 100 of the present example can avoid the destructive failure of the switching device when short circuit actually occurs. On the other hand, when short circuit detection is an erroneous detection, that is, when normal control is reinstated before the number of switching events at the first ON width exceeds the reference number, the switching control circuit 100 of the present example can improve the efficiency as compared to a case where the switching device is stopped in response to short circuit detection.

When the short circuit determination unit 130 determines that the current detection resistor is short circuited, the driving unit 140 may change drive of the switching device from drive corresponding to the feedback voltage to different drive. For example, when the current detection resistor is not short circuited, the driving unit 140 drives the switching device by the pulse width modulation method or the pulse frequency modulation method based on the feedback voltage.

When the driving unit 140 drives the switching device by the pulse width modulation method corresponding to the feedback voltage, the duty ratio of the switching device is decided based on the feedback voltage. That is, the drive corresponding to the feedback voltage may be drive by deciding the duty ratio of the switching device based on the feedback voltage. When the short circuit determination unit 130 determines that the current detection resistor is short circuited, the driving unit 140 may change the duty ratio for controlling the switching device to the predetermined first duty ratio as different drive.

When the driving unit 140 drives the switching device by the pulse frequency modulation method corresponding to the feedback voltage, the ON width of the switching device is decided based on the feedback voltage. That is, the drive corresponding to the feedback voltage may be drive by deciding the ON width of the switching device based on the feedback voltage. When the short circuit determination unit 130 determines that the current detection resistor is short circuited, the driving unit 140 may change the ON width for turning on the switching device to the predetermined first ON width as different drive.

When the current detection resistor is short circuited, control based on the feedback signal is not appropriately performed, and the current which flows through the switching device becomes excessive. In this case, there is a risk that the switching device may suffer the destructive failure due to self-heating. Alternatively, the output voltage increases, and the switching device is stopped through the output overvoltage protection operation. To avoid the destructive failure of the switching device, the switching device with a rated current value larger than a capacity of the power source system may need to be used.

The switching control circuit 100 of the present example includes the short circuit determination unit 130 and the driving unit 140, and when it is determined that the current detection resistor is short circuited, the driving unit 140 changes drive of the switching device from drive corresponding to the feedback voltage to the different drive. With this configuration, since the stress due to heat generation of the switching device can be reduced, even when the switching device with a small rated current value is used, the destructive failure of the switching device can be avoided.

In addition, in the switching control circuit 100 of the present example, when it is determined that the current detection resistor is short circuited, the driving unit 140 changes the drive to the different drive without stopping the switching device. With this configuration, even when short circuit of the current detection resistor is erroneously detected due to an instantaneous voltage drop or the like of the AC input voltage, the switching control circuit 100 of the present example can avoid the destructive failure of the switching device while the output voltage is being generated. Therefore, the switching control circuit 100 of the present example can improve the efficiency as compared to a case where the switching device is stopped in response to short circuit detection.

A flow of a determination by the short circuit determination unit 130 on whether or not short circuit of the current detection resistor occurs and of a change of the drive method by the driving unit 140 may be performed for each switching cycle of the switching device. For example, in a case where it is determined that short circuit occurs in a certain cycle and the drive is changed to different drive, when it is determined that short circuit does not occur in the next cycle, the driving unit 140 may end the different drive and return to normal drive. As another example, in a case where it is determined that short circuit occurs in a certain cycle and the drive is changed to different drive, when it is still determined that short circuit also occurs in the next cycle, the driving unit 140 may continue the different drive.

The driving unit 140 does not change the drive of the switching device to different drive depending on the AC input voltage detected by the input detection voltage acquisition unit 110. For example, when a phase angle of the AC input voltage is low, the AC input voltage may be low, and short circuit of the current detection resistor may be erroneously detected. In addition, short circuit of the current detection resistor may be erroneously detected due to an instantaneous voltage drop or the like of the AC input voltage. In the switching control circuit 100 of the present example, the driving unit 140 does not change the drive of the switching device to the different drive depending on the AC input voltage detected by the input detection voltage acquisition unit 110. With this configuration, even when short circuit of the current detection resistor is erroneously detected, the switching control circuit 100 of the present example can avoid the destructive failure of the switching device while the output voltage is being generated, and can improve the efficiency as compared to a case where the switching device is stopped in response to short circuit detection.

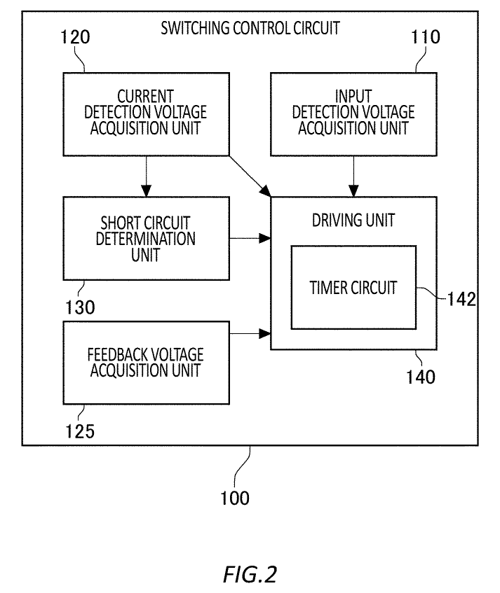

FIG. 2 illustrates an overview of a configuration of a modified example of the switching control circuit 100. The switching control circuit 100 of the present example is a switching control circuit which controls a switching device included in a power source system which generates an output voltage from an AC input voltage. The switching control circuit 100 includes the input detection voltage acquisition unit 110, the current detection voltage acquisition unit 120, the feedback voltage acquisition unit 125, the short circuit determination unit 130, and the driving unit 140. The driving unit 140 has a timer circuit 142. The input detection voltage acquisition unit 110, the current detection voltage acquisition unit 120, the feedback voltage acquisition unit 125, and the short circuit determination unit 130 may have configurations similar to those described with reference to FIG. 1.

When the short circuit determination unit 130 determines that the current detection resistor is short circuited, the timer circuit 142 counts a number of at least one switching event of the switching device. When the timer circuit 142 determines that the number of at least one switching event is equal to or greater than a predetermined reference number, the timer circuit 142 may output a signal for stopping drive of a switching device 20 to the driving unit 140. When the number of switching events counted by the timer circuit 142 exceeds the predetermined reference number, the driving unit 140 may stop drive of the switching device or drive the switching device under a minimum drive condition. The drive of the switching device under the minimum drive condition may include setting the duty ratio to the minimum duty ratio in the pulse width modulation method or may include setting the ON width to the minimum ON width in the pulse frequency modulation method.

The driving unit 140 resets count of the timer circuit 142 depending on the input detection voltage. For example, when a determination value based on the input detection voltage is lower than a predetermined count reference value, the driving unit 140 resets the count of the timer circuit 142.

For example, when a phase angle of the AC input voltage is low, the AC input voltage may be low, and short circuit of the current detection resistor may be erroneously detected. In addition, short circuit of the current detection resistor may be erroneously detected due to an instantaneous voltage drop or the like of the AC input voltage. In the switching control circuit 100 of the present example, the driving unit 140 resets the count of the timer circuit 142 depending on the input detection voltage. That is, the driving unit 140 stops the drive of the switching device, or the count for the drive under the minimum drive condition is reset. With this configuration, even when short circuit of the current detection resistor is erroneously detected, the switching control circuit 100 of the present example can avoid the destructive failure of the switching device while the output voltage is being generated, and can improve the efficiency as compared to a case where the switching device is stopped in response to short circuit detection.

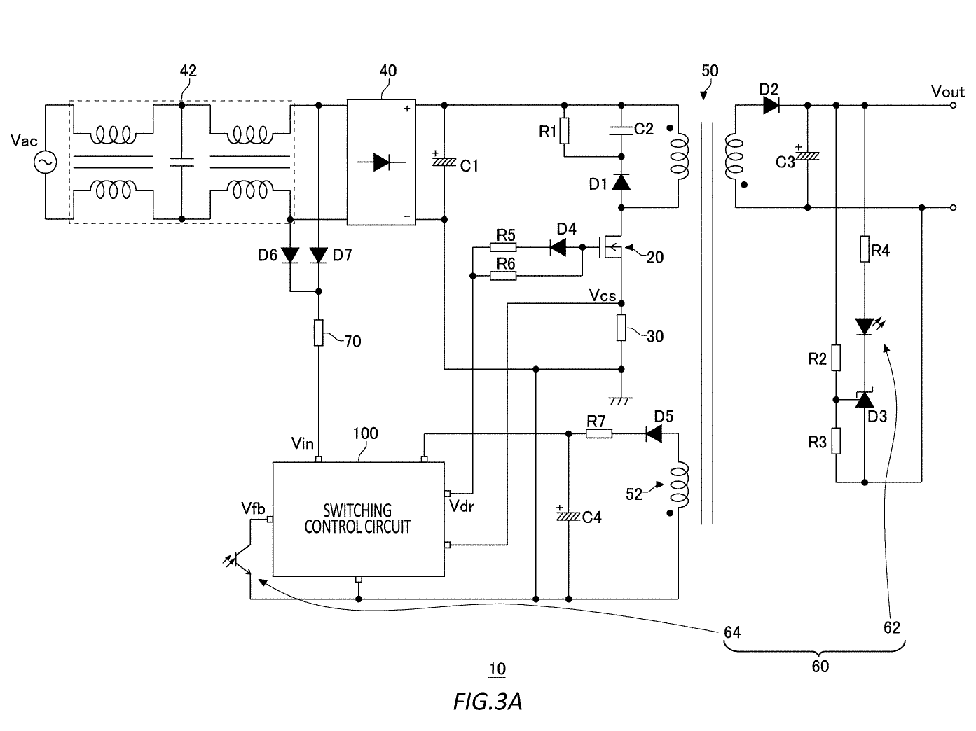

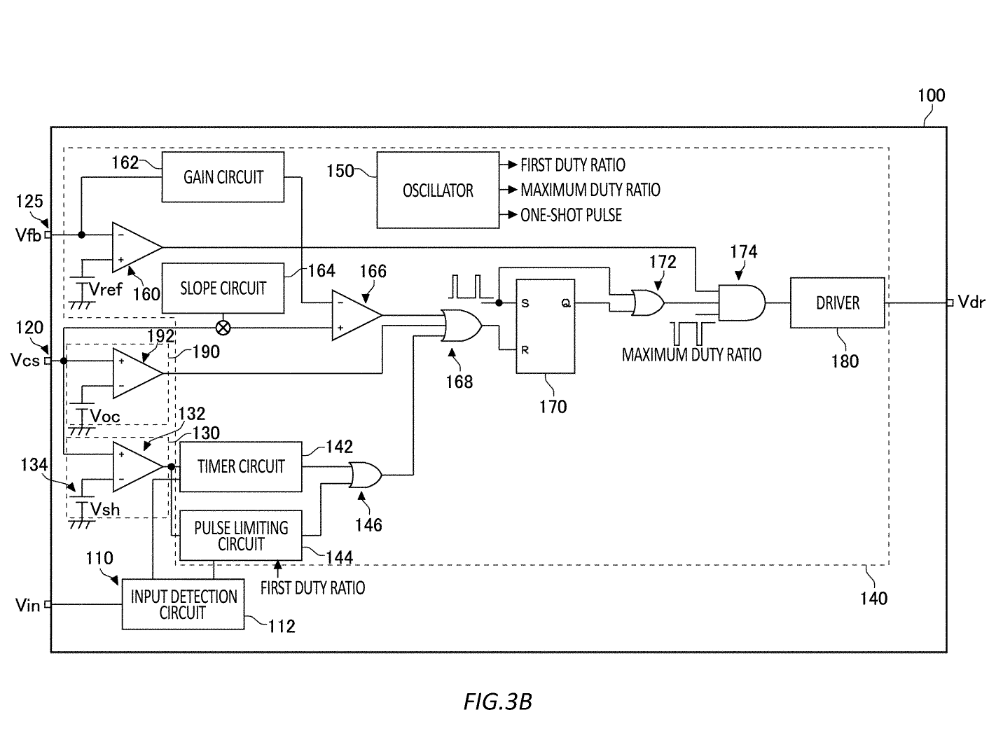

FIG. 3A illustrates an example of a power source system 10 which includes the switching control circuit 100. The power source system 10 includes the switching control circuit 100, the switching device 20, and a current detection resistor 30. The power source system 10 of the present example is a flyback power source system. The switching control circuit 100 of the present example drives the switching device 20 by the pulse width modulation method. It is noted however that a configuration of the power source system and a drive system of the switching device 20 are not limited to the present example.

The power source system 10 of the present example is a power source system which generates an output voltage Vout from a voltage obtained when a diode bridge 40 performs full-wave rectification on an AC input voltage Vac. Noise may be reduced by a noise reduction circuit 42 before the AC input voltage Vac is rectified by the diode bridge 40. The voltage rectified by the diode bridge 40 may be smoothened by a capacitor C1 and thereafter input to a transformer 50.

A snubber circuit formed of a diode D1, a capacitor C2, and a resistor R1 is provided on a primary side of the transformer 50 to suppress a voltage overshoot. A voltage generated on a secondary side of the transformer 50 is rectified by a diode D2 and smoothened by a capacitor C3. The output voltage Vout is divided by a resistor R2 and a resistor R3 and input to a shunt regulator D3. The shunt regulator D3 generates a current such that the input voltage becomes equal to an internal reference voltage source, and a current flows through a path formed of a resistor R4 and a light emitting diode 62 of a photocoupler 60. With this configuration, the output voltage Vout is fed back to the switching control circuit 100 via the photocoupler 60.

The switching control circuit 100 generates a drive voltage Vdr and drives the switching device 20. The switching control circuit 100 may be connected to a gate of the switching device 20 via a diode D4, a resistor R5, and a resistor R6. With this configuration, different gate resistance values are set when the switching device 20 is on and when it is off.

The switching control circuit 100 is provided on the primary side of the transformer 50 and controls the switching device 20 based on the feedback signal from the secondary side of the transformer 50 such that the output voltage Vout becomes constant. For example, the photocoupler 60 formed of the light emitting diode 62 provided on the secondary side and a phototransistor 64 provided on the primary side generates a feedback voltage VfB. The switching control circuit 100 may control the switching device 20 by comparing a current detection voltage Vcs generated in the current detection resistor 30 with the feedback voltage VfB. A voltage generated in an auxiliary winding 52 may be rectified and smoothened via a diode D5, a resistor R7, and a capacitor C4 and supplied as a power source of the switching control circuit 100.

In the present example, the input detection voltage acquisition unit 110 of the switching control circuit 100 acquires, as an input detection voltage Vin, a voltage obtained when a voltage drop due to a resistor 70 occurs in a voltage obtained by performing full-wave rectification on the AC input voltage Vac by a diode D6 and a diode D7. The current detection voltage acquisition unit 120 of the switching control circuit 100 acquires the current detection voltage Vcs generated in the current detection resistor 30 which detects the current flowing through the switching device 20.

FIG. 3B illustrates an example of the switching control circuit 100 formed as an IC. The switching control circuit 100 is an example of the switching control circuit 100 included in the power source system 10 of FIG. 3A. The switching control circuit 100 of the present example includes the input detection voltage acquisition unit 110, the current detection voltage acquisition unit 120, the short circuit determination unit 130, and the driving unit 140. The switching control circuit 100 may include an overcurrent determination unit 190.

The input detection voltage acquisition unit 110 acquires the input detection voltage Vin corresponding to the AC input voltage Vac. The input detection voltage acquisition unit 110 may have an input detection circuit 112. The input detection circuit 112 may supply a signal corresponding to the input detection voltage Vin to the driving unit 140.

The current detection voltage acquisition unit 120 acquires the current detection voltage Vcs generated in the current detection resistor 30 which detects a current flowing through the switching device 20. The current detection voltage acquisition unit 120 may supply the current detection voltage Vcs to the short circuit determination unit 130, the driving unit 140, and the overcurrent determination unit 190.

The feedback voltage acquisition unit 125 acquires the feedback voltage VfB corresponding to the output voltage Vout. The feedback voltage acquisition unit 125 may supply the feedback voltage VfB to the driving unit 140.

The short circuit determination unit 130 may have a comparator 132 and a voltage generation unit 134. The current detection voltage Vcs is input to a non-inverting input terminal of the comparator 132, and a short circuit threshold voltage Vsh is input to an inverting input terminal of the comparator 132. The comparator 132 outputs a signal at high level when the current detection voltage Vcs is equal to or greater than the short circuit threshold voltage Vsh and outputs a signal at low level when the current detection voltage Vcs is smaller than the short circuit threshold voltage Vsh. That is, when it is determined that the current detection resistor 30 is short circuited, the comparator 132 outputs the signal at low level. The comparator 132 may supply a signal corresponding to a comparison result to the driving unit 140. The voltage generation unit 134 generates the predetermined short circuit threshold voltage Vsh.

The driving unit 140 may have the timer circuit 142 and a pulse limiting circuit 144. The driving unit 140 may have an OR circuit 146, an oscillator 150, a comparator 160, a gain circuit 162, a slope circuit 164, a comparator 166, an OR circuit 168, a flip-flop circuit 170, an OR circuit 172, an AND circuit 174, and a driver 180.

The timer circuit 142 may count the number of switching events of the switching device 20. For example, when the short circuit determination unit 130 determines that the current detection resistor 30 is short circuited, the timer circuit 142 counts the number of switching events of the switching device 20. The timer circuit 142 may be reset depending on the signal at high level from the comparator 132. That is, when it is determined that the current detection voltage Vcs is equal to or greater than the short circuit threshold voltage Vsh and the current detection resistor 30 is not short circuited, the timer circuit 142 may be reset, and when it is determined that the current detection voltage Vcs is smaller than the short circuit threshold voltage Vsh and the current detection resistor 30 is short circuited, the timer circuit 142 may sustain the count.

The timer circuit 142 may be reset depending on a signal from the input detection circuit 112. For example, when a determination value based on the input detection voltage Vin is lower than a predetermined count reference value, the timer circuit 142 is reset. The determination value based on the input detection voltage Vin may be a voltage value itself of the input detection voltage Vin or may be a value calculated from the input detection voltage Vin. For example, the determination value may be a value calculated such that the voltage drop due to the resistor 70 is to be compensated.

In the switching control circuit 100 of the present example, the count of the timer circuit 142 is reset depending on the input detection voltage Vin. With this configuration, even when short circuit of the current detection resistor 30 due to an instantaneous voltage drop or the like of the AC input voltage Vac is erroneously detected, the switching control circuit 100 of the present example can avoid the destructive failure of the switching device 20 while the output voltage Vout is being generated, and can improve the efficiency as compared to a case where the switching device 20 is stopped in response to short circuit detection.

The pulse limiting circuit 144 may generate a signal for limiting the duty ratio of the switching device 20 to the first duty ratio. For example, the pulse limiting circuit 144 generates the signal for limiting the duty ratio of the switching device 20 to the first duty ratio based on a signal at the first duty ratio which is generated by the oscillator 150.

The pulse limiting circuit 144 may generate the signal for limiting the duty ratio of the switching device 20 to the first duty ratio depending on a signal from the comparator 132. For example, the pulse limiting circuit 144 generates the signal for limiting the duty ratio of the switching device 20 to the first duty ratio when a signal from the comparator 132 is low level and does not generate the signal for limiting the duty ratio of the switching device 20 to the first duty ratio when a signal from the comparator 132 is high level. That is, when it is determined that the current detection resistor 30 is short circuited, the pulse limiting circuit 144 may generate the signal for limiting the duty ratio of the switching device 20 to the first duty ratio.

In the switching control circuit 100 of the present example, when it is determined that the current detection resistor 30 is short circuited, the pulse limiting circuit 144 generates the signal for limiting the duty ratio of the switching device 20 to the first duty ratio. With this configuration, even when short circuit of the current detection resistor 30 due to an instantaneous voltage drop or the like of the AC input voltage is erroneously detected, the switching control circuit 100 of the present example can avoid the destructive failure of the switching device 20 while the output voltage is being generated, and can improve the efficiency as compared to a case where the switching device 20 is stopped in response to short circuit detection.

The feedback voltage VfB is compared with a reference voltage Vref by the comparator 160. The comparator 160 may output a comparison result to the AND circuit 174. According to this configuration, in such a case where the output voltage Vout becomes a voltage higher than a predetermined voltage which corresponds to a moment when the feedback voltage Vfb is lower than the reference voltage Vref, it is possible to stop a switching operation and increase a safety of the power source system (overvoltage determination processing). A signal obtained when the feedback voltage VfB is amplified by the gain circuit 162 is input to an inverting input terminal of the comparator 166. A signal obtained when the current detection voltage Vcs is subjected to slope compensation by the slope circuit 164 is input to a non-inverting input terminal of the comparator 166. With this configuration, the feedback voltage VfB is compared with the current detection voltage Vcs.

The oscillator 150 outputs a one-shot pulse. The one-shot pulse output by the oscillator 150 is input to a set terminal S of the flip-flop circuit 170. With this configuration, on of the switching device 20 is generated. When short circuit of the current detection resistor 30 does not occur, the current detection voltage Vcs increases in response to the switching device 20 being on. When the voltage obtained when the current detection voltage Vcs is subjected to the slope compensation by the slope circuit 164 becomes larger than an output signal of the gain circuit 162, the comparator 166 outputs the signal at high level, and the signal at high level is input to the OR circuit 168. With this configuration, since the signal at high level is input to a reset terminal R of the flip-flop circuit 170, the duty ratio of the drive voltage Vdr for the driver 180 to drive the switching device 20 is set via the OR circuit 172 and the AND circuit 174. In this manner, the switching control circuit 100 of the present example may control the switching device 20 by the pulse width modulation method.

When short circuit of the current detection resistor 30 occurs, since the current detection voltage Vcs does not increase, the comparator 166 continues outputting the signal at low level. With this configuration, the signal at high level is not input to the reset terminal R of the flip-flop circuit 170, and the pulse width for controlling the switching device 20 becomes maximum, and there is a risk that the switching device 20 may suffer the destructive failure due to self-heating. In the switching control circuit 100 of the present example, when it is determined that the current detection resistor 30 is short circuited, the pulse limiting circuit 144 generates the signal for limiting the duty ratio of the switching device 20 to the first duty ratio, and the signal is input to the OR circuit 168 via the OR circuit 146. With this configuration, since an output of the OR circuit 168 turns to high level and the signal at high level is input to the reset terminal R of the flip-flop circuit 170, the duty ratio of the drive voltage Vdr for the driver 180 to drive the switching device 20 is set to the first duty ratio via the OR circuit 172 and the AND circuit 174. Thus, since the stress due to heat generation of the switching device 20 can be reduced, even when the switching device 20 with a small rated current value is used, the destructive failure of the switching device 20 can be avoided.

In addition, in the switching control circuit 100 of the present example, when it is determined that the current detection resistor 30 is short circuited, the driving unit 140 changes the duty ratio to the first duty ratio without stopping the switching device 20. With this configuration, even when short circuit of the current detection resistor is erroneously detected due to an instantaneous voltage drop or the like of the AC input voltage, the switching control circuit 100 of the present example can avoid the destructive failure of the switching device 20 while the output voltage is being generated. Therefore, the switching control circuit 100 of the present example can improve the efficiency as compared to a case where the switching device 20 is stopped in response to short circuit detection.

A flow of a determination by the short circuit determination unit 130 on whether or not short circuit of the current detection resistor 30 occurs, a change of the duty ratio by the driving unit 140, and a determination by the driving unit 140 on whether or not the count of the timer circuit 142 is to be reset may be performed for each switching cycle of the switching device 20. For example, in a case where it is determined that short circuit occurs in a certain cycle and the duty ratio is changed to the first duty ratio, when it is determined that short circuit does not occur in the next cycle, the driving unit 140 may end control by the first duty ratio and return to normal control based on the current detection voltage Vcs and the feedback voltage VfB. As another example, in a case where it is determined that short circuit occurs in a certain cycle and the duty ratio is changed to the first duty ratio, when it is still determined that short circuit also occurs in the next cycle, the driving unit 140 may continue the control by the first duty ratio.

When a number of at least one switching event of the switching device 20 at the first duty ratio exceeds a predetermined reference number, the driving unit 140 may change the duty ratio for controlling the switching device 20 to the second duty ratio that is smaller than the first duty ratio. For example, when the timer circuit 142 counts the predetermined reference number, the signal at high level continues to be input to the reset terminal R of the flip-flop circuit 170. With this configuration, the duty ratio for controlling the switching device 20 is changed to the second duty ratio.

In the switching control circuit 100 of the present example, a signal corresponding to a set pulse input to the set terminal S of the flip-flop circuit 170 is also input to the driver 180 via the OR circuit 172 and the AND circuit 174. The second duty ratio may be a duty ratio of the set pulse. For example, the duty ratio of the set pulse is a predetermined minimum duty ratio for driving the switching device 20. When the switching device 20 is completely stopped, reinstation of the switching device 20 may become difficult. Since the switching device 20 continues to be driven at the minimum duty ratio without being completely stopped, it is possible to facilitate the reinstation of the switching device 20. It is noted however that the switching device 20 may be completely stopped without a signal corresponding to set pulse being input to the driver 180. In this case the second duty ratio is 0.

In the switching control circuit 100 of the present example, when it is determined that the current detection resistor 30 is short circuited, the driving unit 140 sets the duty ratio of the switching device 20 to the first duty ratio, and the timer circuit 142 counts the number of switching events of the switching device 20. On the other hand, the driving unit 140 may reset the count of the timer circuit 142 depending on the input detection voltage Vin. For example, even when the count of the timer circuit 142 is reset depending on the input detection voltage Vin, the duty ratio of the switching device 20 may be set to the first duty ratio. That is, even when the count of the timer circuit 142 is reset to avoid erroneous detection of short circuit of the current detection resistor 30, since there are cases where short circuit of the current detection resistor 30 actually occurs, the duty ratio of the switching device 20 may be set to the first duty ratio.

The overcurrent determination unit 190 may determine whether or not an overcurrent flow through the switching device 20 by comparing the current detection voltage Vcs with a predetermined overcurrent threshold voltage Voc. When the current detection voltage Vcs becomes larger than the overcurrent threshold voltage Voc, since the signal at high level is output from a comparator 192 and the signal at high level continues to be input to the reset terminal R of the flip-flop circuit 170, the switching device 20 is driven at the minimum duty ratio or stopped. With this configuration, destructive failure of the switching device 20 due to an overcurrent can be avoided.

The short circuit threshold voltage Vsh may be one fortieth or more and one tenth or less of the overcurrent threshold voltage Voc. For example, the short circuit threshold voltage Vsh is one twentieth of the overcurrent threshold voltage Voc.

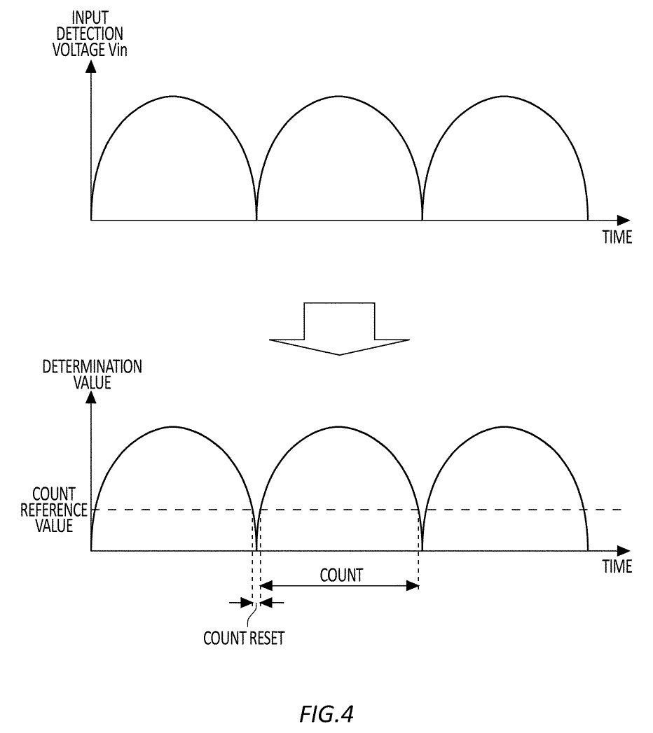

FIG. 4 illustrates an example of the input detection voltage and the determination value. A top graph represents a change over time of the input detection voltage Vin, and a bottom graph represents a change over time of the determination value.

The determination value based on the input detection voltage Vin may be a voltage value itself of the input detection voltage Vin or may be a value calculated from the input detection voltage Vin. For example, the determination value may be a value calculated such that the voltage drop due to the resistor 70 is to be compensated.

When the determination value based on the input detection voltage Vin is lower than the predetermined count reference value, the driving unit 140 may reset the count of the timer circuit 142. The count of the timer circuit 142 may be reset in a section in which a determination value represented by a solid line is below a count reference value of a dashed line, and the count of the timer circuit 142 may continue in a section in which the determination value represented by the solid line exceeds the count reference value of the dashed line. In the switching control circuit 100 of the present example, since the driving unit 140 resets the count of the timer circuit 142 depending on the input detection voltage Vin, even when short circuit of the current detection resistor 30 is erroneously detected, the switching control circuit 100 of the present example can avoid the destructive failure of the switching device 20 while the output voltage is being generated, and can improve the efficiency as compared to a case where the switching device 20 is stopped in response to short circuit detection.

The count reference value may be decided so as to be equivalent to a range in which the AC input voltage Vac becomes a low phase angle. For example, the count reference value may be set so as to correspond to the determination value when the phase angle of the AC input voltage Vac is 45 degrees and 135 degrees. Alternatively, a minimum value of input voltage detection (threshold to perform the reset) may be set. With this configuration, when the phase angle of the AC input voltage Vac is in a range of 45 degrees or less or 135 degrees or more or in a case of the minimum value of the input voltage or less, the driving unit 140 may reset the count of the timer circuit 142.

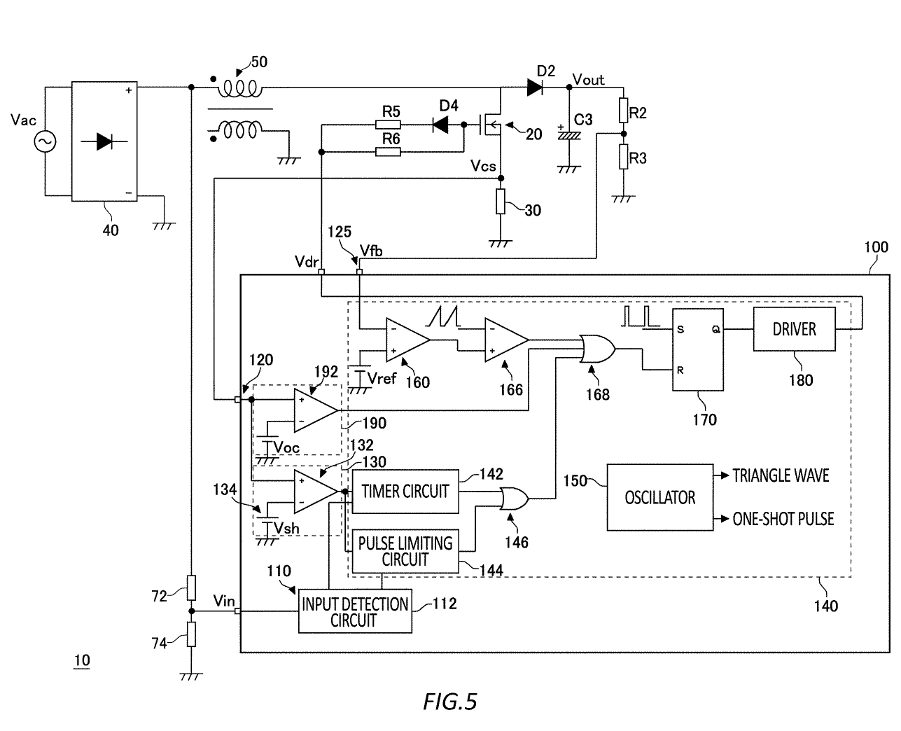

FIG. 5 illustrates an example of the power source system 10 which includes the switching control circuit 100. The power source system 10 includes the switching control circuit 100, the switching device 20, and a current detection resistor 30. The power source system 10 of the present example is a PFC power source system. The power source system 10 may be a PFC power source system which operates in a current continuous mode or a current discontinuous mode. The switching control circuit 100 of the present example drives the switching device 20 by the pulse width modulation method. It is noted however that a configuration of the power source system and a drive system of the switching device 20 are not limited to the present example. In the present example, different aspects from the example described in connection to FIG. 3A and FIG. 3B will be described in particular, and other aspects may be the same as the example described in connection to FIG. 3A and FIG. 3B.

The power source system 10 of the present example is a power source system which generates the output voltage Vout from a voltage obtained when a diode bridge 40 performs full-wave rectification on an AC input voltage Vac. The switching control circuit 100 generates the drive voltage Vdr and drives the switching device 20. The switching control circuit 100 controls the switching device 20 such that the output voltage Vout becomes constant. For example, the output voltage Vout is divided by the resistor R2 and the resistor R3 to generate the feedback voltage VfB. The switching control circuit 100 may control the switching device 20 by comparing a voltage obtained by converting the feedback voltage VfB by an error amplifier or the like with a triangle wave which increases at a constant gradient after the switching device 20 is turned on.

The oscillator 150 outputs a one-shot pulse and a triangle wave. The one-shot pulse output by the oscillator 150 is input to a set terminal S of the flip-flop circuit 170. With this configuration, on of the switching device 20 is generated. The triangle wave output by the oscillator 150 is input to the inverting input terminal of the comparator 166. The triangle wave output by the oscillator 150 increases at a constant gradient according to rise of one-shot pulse output by the oscillator 150. When the output signal of the comparator 160 becomes larger than the triangle wave, the comparator 166 outputs the signal at high level, and the signal at high level is input to the OR circuit 168. With this configuration, since the signal at high level is input to the reset terminal R of the flip-flop circuit 170, the duty ratio of the drive voltage Vdr for the driver 180 to drive the switching device 20 is set via the OR circuit 172 and the AND circuit 174. In this manner, the switching control circuit 100 of the present example may control the switching device 20 by the pulse width modulation method.

In the present example, the input detection voltage acquisition unit 110 of the switching control circuit 100 acquires, as the input detection voltage Vin, a voltage obtained when the AC input voltage Vac is subjected to full-wave rectification and divided by a resistor 72 and a resistor 74. The current detection voltage acquisition unit 120 of the switching control circuit 100 acquires the current detection voltage Vcs generated in the current detection resistor 30 which detects the current flowing through the switching device 20.

Operations in connection to the timer circuit 142 and the pulse limiting circuit 144 are similar of those of the example described in connection to FIG. 3A and FIG. 3B. Therefore, since the switching control circuit 100 of the present example can reduce the stress due to heat generation of the switching device 20, even when the switching device 20 with a small rated current value is used, destructive failure of the switching device 20 can be avoided. In addition, even when short circuit of the current detection resistor 30 due to an instantaneous voltage drop or the like of the AC input voltage Vac is erroneously detected, the switching control circuit 100 of the present example can avoid the destructive failure of the switching device 20 while the output voltage Vout is being generated, and can improve the efficiency as compared to a case where the switching device 20 is stopped in response to short circuit detection.

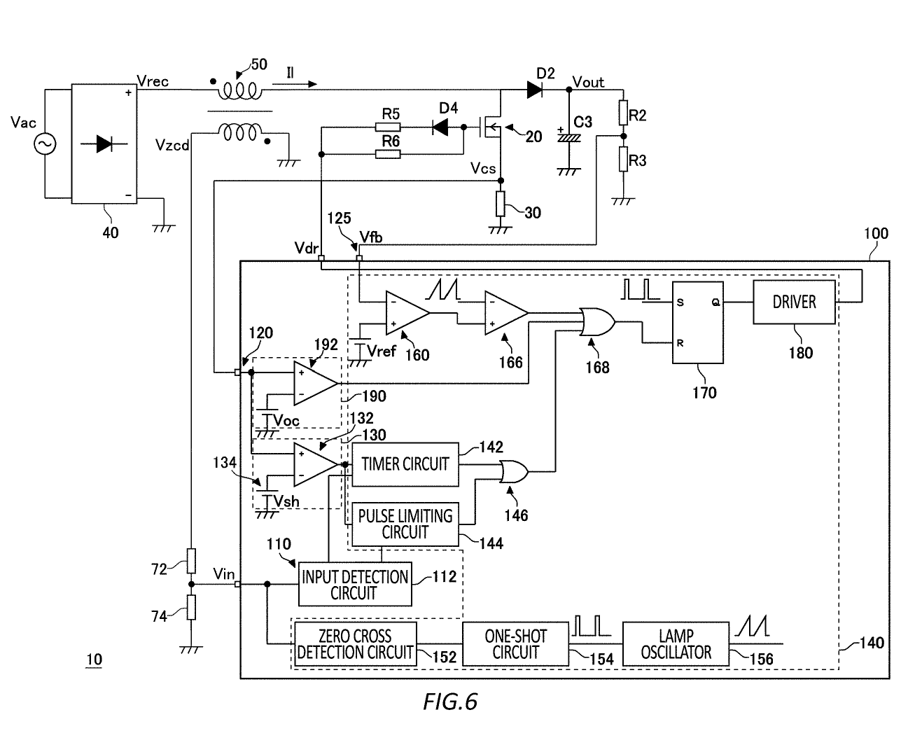

FIG. 6 illustrates an example of the power source system 10 which includes the switching control circuit 100. The power source system 10 includes the switching control circuit 100, the switching device 20, and a current detection resistor 30. The power source system 10 of the present example is a PFC power source system. The power source system 10 may be a PFC power source system which operates in a current critical mode. The switching control circuit 100 of the present example drives the switching device 20 by the pulse frequency modulation method. It is noted however that a configuration of the power source system and a drive system of the switching device 20 are not limited to the present example. In the present example, different aspects from the example described in connection to FIG. 3A and FIG. 3B and/or the example of FIG. 5 will be described in particular, and other aspects may be the same as the example described in connection to FIG. 3A and FIG. 3B and/or the example of FIG. 5.

The power source system 10 of the present example is a power source system which generates the output voltage Vout from a voltage obtained when the diode bridge 40 performs full-wave rectification on an AC input voltage Vac. The switching control circuit 100 generates the drive voltage Vdr and drives the switching device 20. The switching control circuit 100 controls the switching device 20 such that the output voltage Vout becomes constant. For example, the output voltage Vout is divided by the resistor R2 and the resistor R3 to generate the feedback voltage VfB. The switching control circuit 100 may control the switching device 20 by comparing a voltage obtained by converting the feedback voltage VfB by an error amplifier or the like with a triangle wave which increases at a constant gradient after the switching device 20 is turned on.

In the present example, the input detection voltage acquisition unit 110 of the switching control circuit 100 acquires, as the input detection voltage Vin, a voltage obtained by dividing a voltage Vzcd generated in the auxiliary winding when a voltage Vrec obtained by performing full-wave rectification on the AC input voltage Vac is input to the main winding of the transformer. The current detection voltage acquisition unit 120 of the switching control circuit 100 acquires the current detection voltage Vcs generated in the current detection resistor 30 which detects the current flowing through the switching device 20.

The driving unit 140 of the present example has a zero cross detection circuit 152, a one-shot circuit 154, and a lamp oscillator 156.

The zero cross detection circuit 152 may detect whether or not an inductor current Il becomes zero based on the input detection voltage Vin. The zero cross detection circuit 152 may detect whether or not the inductor current Il becomes a predetermined current value close to zero based on the input detection voltage Vin. When it is detected that the inductor current Il becomes zero or a predetermined current value close to zero, the zero cross detection circuit 152 may output the signal at high level.

The one-shot circuit 154 may generate a pulse signal at high level with a predetermined period. The one-shot circuit 154 may detect the signal at high level of the zero cross detection circuit 152 and generate the pulse signal at high level.

The lamp oscillator 156 may generate a triangle wave which increases at a constant gradient. The lamp oscillator 156 may generate a triangle wave which increases at a constant gradient depending on a pulse signal at high level of the one-shot circuit 154. The lamp oscillator 156 may supply the generated triangle wave to the comparator 166.

As described above, when it is detected that the inductor current Il becomes zero or the predetermined current value close to zero, the zero cross detection circuit 152 outputs the signal at high level. With this configuration, a pulse at high level is input to the set terminal S of the flip-flop circuit 170 from the one-shot circuit 154, and on of the switching device 20 is generated. When short circuit of the current detection resistor 30 does not occur, by comparing a voltage obtained when the feedback voltage VfB is converted by an error amplifier or the like with the triangle wave generated by the lamp oscillator 156, the comparator 166 outputs the signal at high level, and the signal at high level is input to the OR circuit 168. With this configuration, the signal at high level is input to the reset terminal R of the flip-flop circuit 170, and the ON width of the drive voltage Vdr for the driver 180 to drive the switching device 20 is set. In this manner, the switching control circuit 100 of the present example may control the switching device 20 by the pulse frequency modulation method.

The timer circuit 142 may count the number of switching events of the switching device 20. For example, when the short circuit determination unit 130 determines that the current detection resistor 30 is short circuited, the timer circuit 142 counts the number of switching events of the switching device 20. The timer circuit 142 may be reset depending on the signal at high level from the comparator 132. That is, when it is determined that the current detection voltage Vcs is equal to or greater than the short circuit threshold voltage Vsh and the current detection resistor 30 is not short circuited, the timer circuit 142 may be reset, and when it is determined that the current detection voltage Vcs is smaller than the short circuit threshold voltage Vsh and the current detection resistor 30 is short circuited, the timer circuit 142 may sustain the count.

The timer circuit 142 may be reset depending on a signal from the input detection circuit 112. For example, when a determination value based on the input detection voltage Vin is lower than a predetermined count reference value, the timer circuit 142 is reset. The determination value based on the input detection voltage Vin may be a voltage value itself of the input detection voltage Vin or may be a value calculated from the input detection voltage Vin. For example, the determination value may be a value calculated such that the voltage drop due to the resistor 70 is to be compensated.

In the switching control circuit 100 of the present example, the count of the timer circuit 142 is reset depending on the input detection voltage Vin. With this configuration, even when short circuit of the current detection resistor 30 due to an instantaneous voltage drop or the like of the AC input voltage Vac is erroneously detected, the switching control circuit 100 of the present example can avoid the destructive failure of the switching device 20 while the output voltage Vout is being generated, and can improve the efficiency as compared to a case where the switching device 20 is stopped in response to short circuit detection.

The pulse limiting circuit 144 may generate a signal for limiting the ON width of the switching device 20 to the first ON width. The pulse limiting circuit 144 may generate a signal for limiting the ON width of the switching device 20 to the first ON width depending on a signal from the comparator 132. For example, the pulse limiting circuit 144 generates the signal for limiting the ON width of the switching device 20 to the first ON width when the signal from the comparator 132 is low level and does not generate the signal for limiting the ON width of the switching device 20 to the first ON width when the signal from the comparator 132 is high level. That is, the pulse limiting circuit 144 may generate the signal for limiting the ON width of the switching device 20 to the first ON width when it is determined that the current detection resistor 30 is short circuited.

In the switching control circuit 100 of the present example, when it is determined that the current detection resistor 30 is short circuited, the pulse limiting circuit 144 generates the signal for limiting the ON width of the switching device 20 to the first ON width. With this configuration, even when short circuit of the current detection resistor 30 is erroneously detected, the switching control circuit 100 of the present example can avoid the destructive failure of the switching device 20 while the output voltage is being generated, and can improve the efficiency as compared to a case where the switching device 20 is stopped in response to short circuit detection.

In the switching control circuit 100 of the present example, when it is determined that the current detection resistor 30 is short circuited, the pulse limiting circuit 144 generates the signal for limiting the ON width of the switching device 20 to the first ON width, and the signal is input to the OR circuit 168 via the OR circuit 146. With this configuration, since an output of the OR circuit 168 turns to high level, and the signal at high level is input to the reset terminal R of the flip-flop circuit 170, the ON width of the drive voltage Vdr for the driver 180 to drive the switching device 20 is set to the first ON width. Thus, since the stress due to heat generation of the switching device 20 can be reduced, even when the switching device 20 with a small rated current value is used, the destructive failure of the switching device 20 can be avoided.

In addition, in the switching control circuit 100 of the present example, when it is determined that the current detection resistor 30 is short circuited, the driving unit 140 changes the ON width to the first ON width without stopping the switching device 20. With this configuration, even when short circuit of the current detection resistor is erroneously detected due to an instantaneous voltage drop or the like of the AC input voltage, the switching control circuit 100 of the present example can avoid the destructive failure of the switching device 20 while the output voltage is being generated. Therefore, the switching control circuit 100 of the present example can improve the efficiency as compared to a case where the switching device 20 is stopped in response to short circuit detection.

A flow of a determination by the short circuit determination unit 130 on whether or not short circuit of the current detection resistor 30 occurs, a change of the ON width by the driving unit 140, and a determination by the driving unit 140 on whether or not the count of the timer circuit 142 is to be reset may be performed for each switching cycle of the switching device 20. For example, in a case where it is determined that short circuit occurs in a certain cycle and the ON width is changed to the first ON width, when it is determined that short circuit does not occur in the next cycle, the driving unit 140 may end control by the first ON width and return to normal control based on the feedback voltage VfB and the triangle wave. As another example, in a case where it is determined that short circuit occurs in a certain cycle and the ON width is changed to the first ON width, when it is still determined that short circuit also occurs in the next cycle, the driving unit 140 may continue the control by the first ON width.

When the number of switching events of the switching device at the first ON width exceeds a predetermined reference number, the driving unit 140 may change the ON width for turning on the switching device to a second ON width that is shorter than the first ON width. For example, when the timer circuit 142 counts the predetermined reference number, the signal at high level continues to be input to the reset terminal R of the flip-flop circuit 170. With this configuration, the ON width for controlling the switching device 20 is changed to the second ON width. For example, the second ON width is a predetermined minimum ON width for driving the switching device or 0.

In the switching control circuit 100 of the present example, when it is determined that the current detection resistor 30 is short circuited, the driving unit 140 sets the ON width of the switching device 20 to the first ON width, and the timer circuit 142 counts the number of switching events of the switching device 20. On the other hand, the driving unit 140 may reset the count of the timer circuit 142 depending on the input detection voltage. For example, even when the count of the timer circuit 142 is reset depending on the input detection voltage, the ON width of the switching device 20 may be set to the first ON width. That is, even when the count of the timer circuit 142 is reset to avoid erroneous detection of short circuit of the current detection resistor 30, since there are cases where short circuit of the current detection resistor 30 actually occurs, the ON width of the switching device 20 may be set to the first ON width.

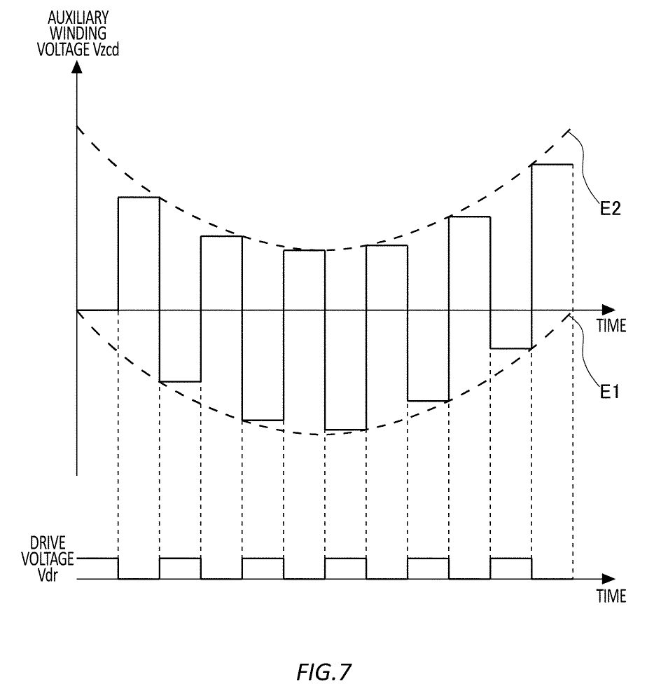

FIG. 7 illustrates an example of an auxiliary winding voltage Vzcd. In this drawing, a change over time of the drive voltage Vdr is illustrated together with a change over time of the auxiliary winding voltage Vzcd.

When the drive voltage Vdr turns to high level and the switching device 20 is turned on, a rectified voltage Vrec is applied to a positive side of the main winding, and a negative side of the main winding becomes a ground voltage when voltage drops of the switching device 20 and the current detection resistor 30 are ignored. In this case, since the auxiliary winding has a polarity opposite to that of the main winding, the auxiliary winding voltage Vzcd is represented as follows: Vzcd = -2^{1/2} × Vrec × Ns/Np. Where Np denotes a number of at least one turn of the main winding, and Ns denotes a number of at least one turn of the auxiliary winding.

On the other hand, when the drive voltage Vdr turns to low level and the switching device 20 is turned off, Vrec is applied to the positive side of the main winding, and Vout is applied to the negative side of the main winding. In this case, since a voltage on the negative side of the main winding becomes higher than a voltage on the positive side, the auxiliary winding voltage Vzcd is represented as follows: Vzcd = Vout - 2^{1/2} × Vrec × (Ns/Np).

Therefore, when the switching device 20 is on, the auxiliary winding voltage Vzcd varies so as to be along an envelope E1 represented as Vzcd = -2^{1/2} × Vrec × (Ns/Np), when the switching device 20 is off, the auxiliary winding voltage Vzcd varies so as to be along an envelope E2 represented as Vzcd = Vout - 2^{1/2} × Vrec × (Ns/Np).

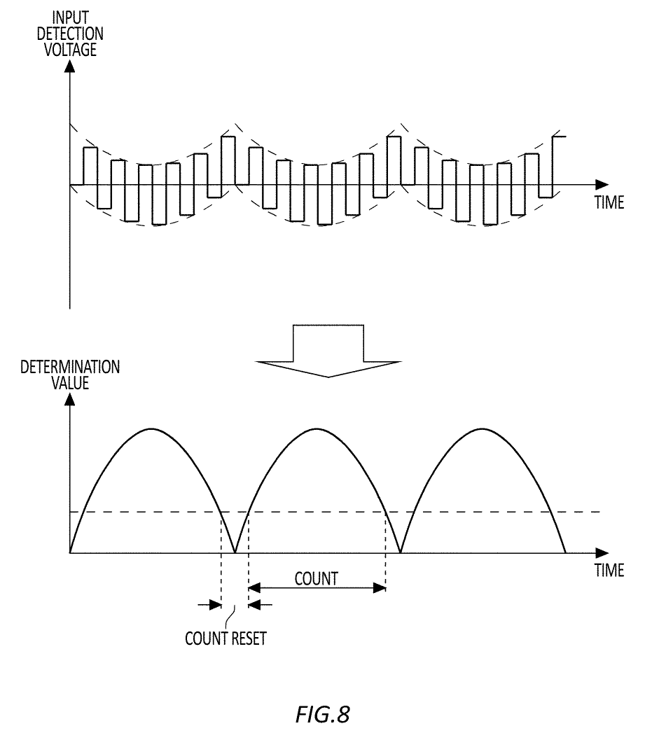

FIG. 8 illustrates an example of the input detection voltage and the determination value. A top graph represents a change over time of the input detection voltage Vin, and a bottom graph represents a change over time of the determination value.

The determination value based on the input detection voltage Vin may be a voltage value itself of the input detection voltage Vin or may be a value calculated from the input detection voltage Vin. As described in connection to FIG. 7, both shapes of the envelope E1 and the envelope E2 of the auxiliary winding voltage Vzcd have shapes corresponding to the rectified voltage Vrec. Therefore, in both cases where the switching device 20 is in an on state and an off state, the rectified voltage Vrec can be calculated based on expressions representing the envelope E1 and the envelope E2. For example, the determination value may be the rectified voltage Vrec calculated based on the input detection voltage Vin.

When the determination value based on the input detection voltage Vin is lower than the predetermined count reference value, the driving unit 140 may reset the count of the timer circuit 142. The count of the timer circuit 142 may be reset in a section in which a determination value represented by a solid line is below a count reference value of a dashed line, and the count of the timer circuit 142 may continue in a section in which the determination value represented by the solid line exceeds the count reference value of the dashed line. In the switching control circuit 100 of the present example, since the driving unit 140 resets the count of the timer circuit 142 depending on the input detection voltage Vin, even when short circuit of the current detection resistor 30 is erroneously detected, the switching control circuit 100 of the present example can avoid the destructive failure of the switching device 20 while the output voltage is being generated, and can improve the efficiency as compared to a case where the switching device 20 is stopped in response to short circuit detection.

For example, the count reference value may be decided so as to be equivalent to a range in which the AC input voltage Vac becomes a low phase angle. For example, the count reference value may be set so as to correspond to the determination value when the phase angle of the AC input voltage Vac is 45 degrees and 135 degrees. With this configuration, when the phase angle of the AC input voltage Vac is in a range of 45 degrees or less or 135 degrees or more, the driving unit 140 may reset the count of the timer circuit 142.

Note that the determination value based on the input detection voltage Vin may be a voltage value itself of the input detection voltage Vin. For example, in a case where the switching device 20 is turned on and the auxiliary winding voltage Vzcd varies along the envelope E1, the driving unit 140 may reset the count of the timer circuit 142 when an absolute value of the input detection voltage Vin is lower than the count reference value. In a case where the switching device 20 is turned off and the auxiliary winding voltage Vzcd varies along the envelope E2, the driving unit 140 may reset the count of the timer circuit 142 when an absolute value of a value obtained by subtracting a voltage corresponding to the output voltage Vout from the input detection voltage Vin is lower than the count reference value.

As described above, the switching control circuit 100 can be adopted in any power source system 10. The switching control circuit 100 may be adopted in any power source system 10 which includes the switching device 20 and the current detection resistor 30. In FIG. 3A and FIG. 3B, FIG. 5, and FIG. 6, the example has been described in which the switching control circuit 100 is adopted to the flyback power source system or the PFC power source system, but the power source system 10 in which the switching control circuit 100 is adopt is not limited to these.

While the present invention has been described by way of the embodiments, the technical scope of the present invention is not limited to the above-described embodiments. It is apparent to persons skilled in the art that various alterations or improvements can be made to the above described embodiments. It is also apparent from description of the claims that the embodiments to which such modifications or improvements are made may be included in the technical scope of the present invention.

It should be noted that each process of the operations, procedures, steps, steps, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as "first" or "next" for the sake of convenience in the claims, specification, or drawings, it does not necessarily mean that the process must be performed in this order.

### EXPLANATION OF REFERENCES

10: power source system; 20: switching device; 30: current detection resistor; 40: diode bridge; 42: noise reduction circuit; 50: transformer; 52: auxiliary winding; 60: photocoupler; 62: light emitting diode; 64: phototransistor; 70: resistor; 72: resistor; 74: resistor; 100: switching control circuit; 110: input detection voltage acquisition unit; 112: input detection circuit; 120: current detection voltage acquisition unit; 125: feedback voltage acquisition unit; 130: short circuit determination unit; 132: comparator; 134: voltage generation unit; 140: driving unit; 142: timer circuit; 144: pulse limiting circuit; 146: OR circuit; 150: oscillator; 152: zero cross detection circuit; 154: one-shot circuit; 156: lamp oscillator; 160: comparator; 162: gain circuit; 164: slope circuit; 166: comparator; 168: OR circuit; 170: flip-flop circuit; 172: OR circuit; 174: AND circuit; 180: driver; 190: overcurrent determination unit; and 192: comparator.

What is claimed is:

1. A switching control circuit which controls a switching device included in a power source system which generates an output voltage from an AC input voltage, the switching control circuit comprising:
an input detection voltage acquisition unit which acquires an input detection voltage corresponding to the AC input voltage;
a current detection voltage acquisition unit which acquires a current detection voltage generated in a current detection resistor which detects a current flowing through the switching device;
a short circuit determination unit which determines, by comparing the current detection voltage with a predetermined short circuit threshold voltage, whether or not the current detection resistor is short circuited; and
a driving unit which drives the switching device by a pulse width modulation method or a pulse frequency modulation method, wherein
when the short circuit determination unit determines that the current detection resistor is short circuited, the driving unit changes a duty ratio for controlling the switching device to a predetermined first duty ratio or changes an ON width for turning on the switching device to a predetermined first ON width.

2. The switching control circuit according to claim 1, wherein
the first duty ratio is smaller than a maximum duty ratio that is preset in the switching control circuit.

3. The switching control circuit according to claim 1, wherein
when a number of at least one switching event of the switching device at the first duty ratio exceeds a predetermined reference number, the driving unit changes the duty ratio for controlling the switching device to a second duty ratio that is smaller than the first duty ratio.

4. The switching control circuit according to claim 3, wherein
the second duty ratio is a predetermined minimum duty ratio for driving the switching device or 0.

5. The switching control circuit according to claim 1, wherein
the first ON width is shorter than a maximum ON width that is preset in the switching control circuit.

6. The switching control circuit according to claim 5, wherein
when a number of at least one switching event of the switching device at the first ON width exceeds a predetermined reference number, the driving unit changes the ON width for turning on the switching device to a second ON width that is shorter than the first ON width.

7. The switching control circuit according to claim 6, wherein
the second ON width is a predetermined minimum ON width for driving the switching device or 0.

8. The switching control circuit according to claim 1, wherein
the driving unit includes a timer circuit which counts a number of at least one switching event of the switching device.

9. The switching control circuit according to claim 8, wherein
the driving unit resets a count of the timer circuit depending on the input detection voltage.

10. The switching control circuit according to claim 9, wherein
when a determination value based on the input detection voltage is lower than a predetermined count reference value, the driving unit resets the count of the timer circuit.

11. The switching control circuit according to claim 2, wherein
the driving unit includes a timer circuit which counts a number of at least one switching event of the switching device.

12. The switching control circuit according to claim 5, wherein
the driving unit includes a timer circuit which counts a number of at least one switching event of the switching device.

13. A switching control circuit which controls a switching device included in a power source system which generates an output voltage from an AC input voltage, the switching control circuit comprising:
an input detection voltage acquisition unit which acquires an input detection voltage corresponding to the AC input voltage;
a current detection voltage acquisition unit which acquires a current detection voltage generated in a current detection resistor which detects a current flowing through the switching device;
a short circuit determination unit which determines, by comparing the current detection voltage with a predetermined short circuit threshold voltage, whether or not the current detection resistor is short circuited; and
a driving unit which drives the switching device, wherein
the driving unit includes a timer circuit which counts a number of at least one switching event of the switching device when the short circuit determination unit determines that the current detection resistor is short circuited,
when the timer circuit determines that the number of at least one switching event is equal to or greater than a predetermined reference number, the timer circuit outputs a signal for stopping drive of the switching device to the driving unit, and
the driving unit resets a count of the timer circuit depending on the input detection voltage.

14. The switching control circuit according to claim 13, wherein
when a determination value based on the input detection voltage is lower than a predetermined count reference value, the driving unit resets the count of the timer circuit.

15. A power source system comprising:
the switching control circuit according to claim 1;
the switching device; and
the current detection resistor.

16. A switching control circuit which controls a switching device included in a power source system which generates an output voltage from an AC input voltage, the switching control circuit comprising:
an input detection voltage acquisition unit which acquires an input detection voltage corresponding to the AC input voltage;
a feedback voltage acquisition unit which acquires a feedback voltage corresponding to the output voltage;
a current detection voltage acquisition unit which acquires a current detection voltage generated in a current detection resistor which detects a current flowing through the switching device;
a short circuit determination unit which determines, by comparing the current detection voltage with a predetermined short circuit threshold voltage, whether or not the current detection resistor is short circuited; and
a driving unit which drives the switching device depending on the feedback voltage acquired by the feedback voltage acquisition unit, wherein
the driving unit
changes drive of the switching device from drive depending on the feedback voltage to different drive when the short circuit determination unit determines that the current detection resistor is short circuited, and
does not change the drive of the switching device to the different drive depending on the AC input voltage detected by the input detection voltage acquisition unit.

17. The switching control circuit according to claim 16, wherein
the driving unit drives the switching device by a pulse width modulation method corresponding to the feedback voltage, and
when the short circuit determination unit determines that the current detection resistor is short circuited, the driving unit changes a duty ratio for controlling the switching device to a predetermined first duty ratio as the different drive.

18. The switching control circuit according to claim 16, wherein
the driving unit drives the switching device by a pulse frequency modulation method corresponding to the feedback voltage, and
when the short circuit determination unit determines that the current detection resistor is short circuited, the driving unit changes an ON width for turning on the switching device to a predetermined first ON width as the different drive.

19. The switching control circuit according to claim 16, wherein
the driving unit includes a timer circuit which counts a number of at least one switching event of the switching device when the short circuit determination unit determines that the current detection resistor is short circuited,
when the timer circuit determines that the number of at least one switching event is equal to or greater than a predetermined reference number, the timer circuit outputs a signal for stopping the drive of the switching device to the driving unit, and
the driving unit resets a count of the timer circuit depending on the input detection voltage.

20. The switching control circuit according to claim 17, wherein
the driving unit includes a timer circuit which counts a number of at least one switching event of the switching device when the short circuit determination unit determines that the current detection resistor is short circuited,
when the timer circuit determines that the number of at least one switching event is equal to or greater than a predetermined reference number, the timer circuit outputs a signal for stopping the drive of the switching device to the driving unit, and
the driving unit resets a count of the timer circuit depending on the input detection voltage.
